(19) United States
(12) Patent Application Publication
(10) Pub. No.: US 2025/0081513 A1
(43) Pub. Date: Mar. 6, 2025

(54) SEMICONDUCTOR DEVICE

(71) Applicant: SAMSUNG ELECTRONICS CO., LTD., SUWON-SI (KR)

(72) Inventors: Tae-Eon BAE, Suwon-si (KR); Hokyun AN, Suwon-si (KR)

(21) Appl. No.: 18/594,049

(22) Filed: Mar. 4, 2024

(30) Foreign Application Priority Data
Aug. 30, 2023 (KR) 10-2023-0114348

(51) Int. Cl. H01L 29/78; H01L 29/10; H01L 29/423; H01L 29/786

(52) U.S. Cl. CPC H10D 30/6215; H10D 30/6757; H10D 62/235; H10D 64/514

(57) ABSTRACT

A semiconductor device includes: a substrate including a first active pattern and a second active pattern which are spaced apart from each other; a first gate structure disposed on the first active pattern; a second gate structure disposed on the second active pattern; and a channel semiconductor pattern disposed between the second active pattern and the second gate structure, wherein the first gate structure includes: a first insulating pattern, a second insulating pattern and a first high-k dielectric pattern, which are stacked on the first active pattern, wherein the second gate structure includes: a third insulating pattern and a second high-k dielectric pattern, which are stacked on the channel semiconductor pattern, and wherein a thickness of the third insulating pattern ranges from 12 Å to 13 Å.

### CROSS-REFERENCE TO RELATED APPLICATION

This U.S. non-provisional patent application claims priority under 35 U.S.C. § 119 to Korean Patent Application No. 10-2023-0114348, filed on Aug. 30, 2023, in the Korean Intellectual Property Office, the disclosure of which is incorporated by reference herein in its entirety.

### TECHNICAL FIELD

Embodiments of the present inventive concept relate to a semiconductor device.

### DISCUSSION OF THE RELATED ART

Semiconductor devices are widely used in an electronic industry because of their small-sized, multi-functionality and/or low-cost characteristics. Semiconductor devices may be categorized as any one of, for example, semiconductor memory devices for storing logical data, semiconductor logic devices for processing logical data, and hybrid semiconductor devices having both the function of the semiconductor memory devices and the function of the semiconductor logic devices.

As high-speed and/or low-power electronic devices have been in demand, high-speed and/or low-voltage semiconductor devices that are used in the electronic devices have also been in demand, and as a result, highly integrated semiconductor devices have been under development. However, reliability and electrical characteristics of semiconductor devices may deteriorate due to the high integration density of the semiconductor devices. Thus, various techniques for increasing reliability and electrical characteristics of semiconductor devices have been under development.

### SUMMARY

According to embodiments of the present inventive concept, a semiconductor device includes: a substrate including a first active pattern and a second active pattern which are spaced apart from each other; a first gate structure disposed on the first active pattern; a second gate structure disposed on the second active pattern; and a channel semiconductor pattern disposed between the second active pattern and the second gate structure, wherein the first gate structure includes: a first insulating pattern, a second insulating pattern and a first high-k dielectric pattern, which are stacked on the first active pattern, wherein the second gate structure includes: a third insulating pattern and a second high-k dielectric pattern, which are stacked on the channel semiconductor pattern, and wherein a thickness of the third insulating pattern ranges from 12 Å to 13 Å.

According to embodiments of the present inventive concept, a semiconductor device includes: a substrate including a first active pattern and a second active pattern which are spaced apart from each other; a first gate structure disposed on the first active pattern; and a second gate structure disposed on the second active pattern, wherein the first gate structure includes: a first insulating pattern, a second insulating pattern, a first high-k dielectric pattern and a first conductive pattern, which are stacked on the first active pattern, wherein the second gate structure includes: a third insulating pattern, a second high-k dielectric pattern and a second conductive pattern, which are stacked on the second active pattern, wherein the first insulating pattern is disposed between the first active pattern and the second insulating pattern, and wherein a thickness of the third insulating pattern is 30% or less of a thickness of the second high-k dielectric pattern.

According to embodiments of the present inventive concept, a semiconductor device includes: a substrate including cell active patterns on a cell region, and a first peripheral active pattern and a second peripheral active pattern spaced apart from each other on a peripheral region that is adjacent to the cell region; word lines disposed in the substrate and intersecting the cell active patterns; bit lines disposed on the substrate and intersecting the word lines; a bit line contact disposed on a central portion of each of the cell active patterns and connected to a corresponding one of the bit lines; storage node contacts disposed on end portions of each of the cell active patterns; a landing pad disposed on each of the storage node contacts; a capacitor disposed on the landing pad; a first peripheral gate pattern disposed on the first peripheral active pattern; a second peripheral gate pattern disposed on the second peripheral active pattern; and a channel semiconductor pattern disposed between the second peripheral active pattern and the second peripheral gate pattern, wherein the first peripheral gate pattern includes: a first insulating pattern, a second insulating pattern, a first high-k dielectric pattern, a first lower conductive pattern, a first upper conductive pattern and a first capping pattern, which are stacked on the first peripheral active pattern, wherein the second peripheral gate pattern includes: a third insulating pattern, a second high-k dielectric pattern, a second lower conductive pattern, a second upper conductive pattern and a second capping pattern, which are stacked on the channel semiconductor pattern, and wherein a sum of a thickness of the first insulating pattern and a thickness of the second insulating pattern ranges from 90% to 110% of a thickness of the third insulating pattern.

### BRIEF DESCRIPTION OF THE DRAWINGS

FIG. 1 is a block diagram illustrating a semiconductor device according to embodiments of the present inventive concept.

FIG. 2 is a plan view illustrating a semiconductor device according to embodiments of the present inventive concept.

FIG. 3 is a cross-sectional view taken along lines A-A′ and B-B′ of FIG. 2 to illustrate a semiconductor device according to embodiments of the present inventive concept.

FIGS. 4A, 4B, 4C, 4D, 4E and 4F are cross-sectional views illustrating a method of manufacturing a semiconductor device according to embodiments of the present inventive concept.

FIG. 5 is a plan view illustrating a semiconductor device according to embodiments of the present inventive concept.

FIG. 6 is a cross-sectional view taken along a line C-C′ of FIG. 5 to illustrate a semiconductor device according to embodiments of the present inventive concept.

### DETAILED DESCRIPTION OF EMBODIMENTS

Embodiments of the present inventive concept will now be described more fully with reference to the accompanying drawings, in which embodiments of the present inventive concept are shown.

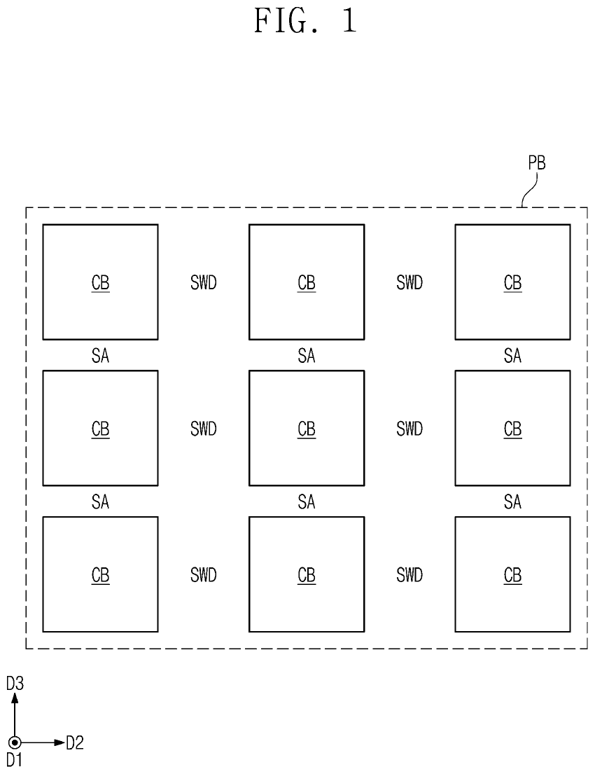

FIG. 1 is a block diagram illustrating a semiconductor device according to embodiments of the present inventive concept.

Referring to FIG. 1, a semiconductor device may include cell blocks CB and a peripheral block PB at least partially surrounding each of the cell blocks CB. The semiconductor device may be a memory device, and each of the cell blocks CB may include a cell circuit such as a memory integrated circuit. The peripheral block PB may include various peripheral circuits for operating the cell circuit, and the peripheral circuits may be electrically connected to the cell circuit.

The peripheral block PB may include sense amplifier circuits SA and sub-word line driver circuits SWD. For example, the sense amplifier circuits SA may face each other with the cell block CB interposed therebetween, and the sub-word line driver circuits SWD may face each other with the cell block CB interposed therebetween. The peripheral block PB may further include power and ground driver circuits for driving the sense amplifier, but embodiments of the present inventive concept are not limited thereto.

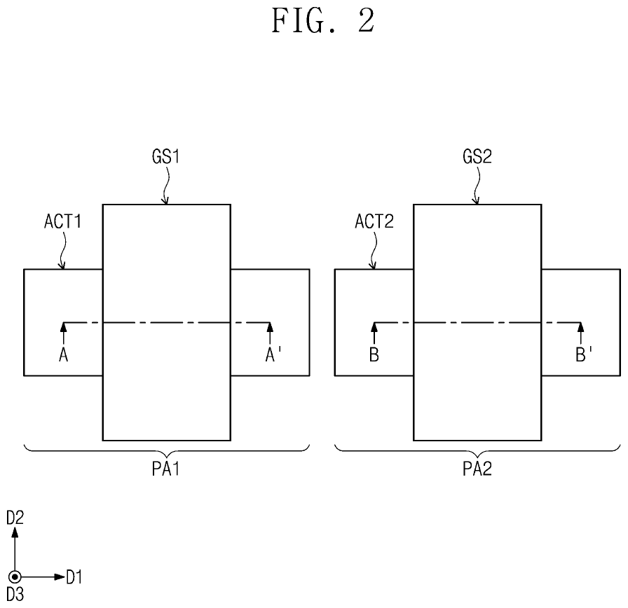

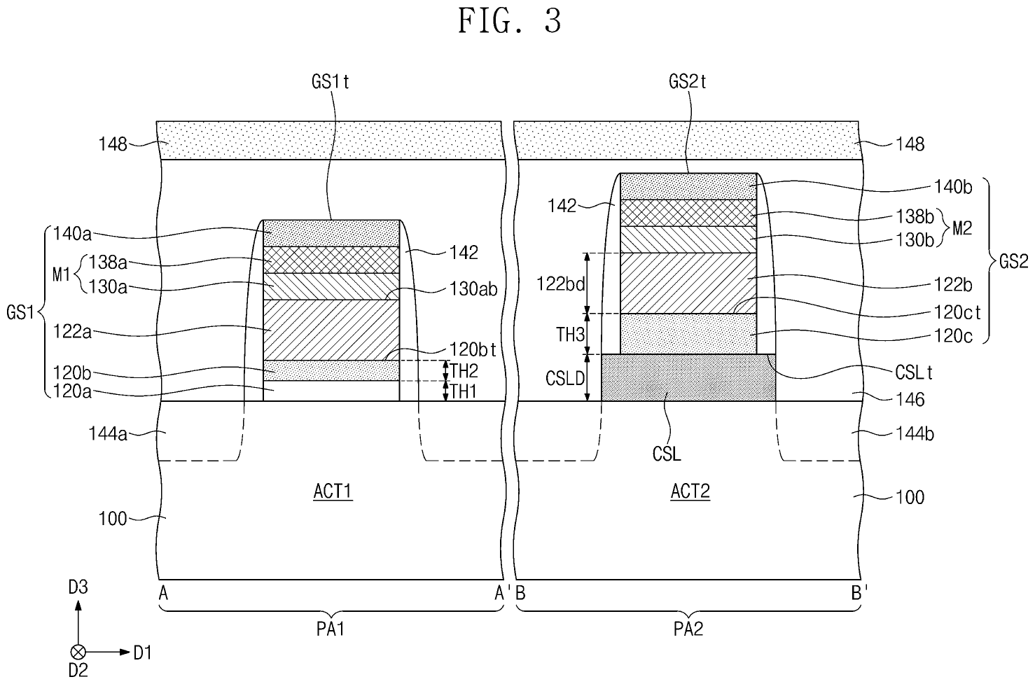

FIG. 2 is a plan view illustrating a semiconductor device according to embodiments of the present inventive concept. FIG. 3 is a cross-sectional view taken along lines A-A′ and B-B′ of FIG. 2 to illustrate a semiconductor device according to embodiments of the present inventive concept.

Referring to FIGS. 2 and 3, a semiconductor device according to embodiments of the present inventive concept may include a substrate 100, a first gate structure GS1, and a second gate structure GS2.

The substrate 100 may include a first peripheral region PA1 and a second peripheral region PA2. The first and second peripheral regions PA1 and PA2 may be regions of the substrate 100, on which the peripheral block PB of FIG. 1 is provided. For example, the substrate 100 may be a silicon substrate. In embodiments of the present inventive concept, the substrate 100 may be a silicon-on-insulator (SOI) substrate.

In the present specification, a first direction D1 may be a direction parallel to a top surface of the substrate 100. A second direction D2 may be a direction which is parallel to the top surface of the substrate 100 and intersects with the first direction D1. A third direction D3 may be a direction that is substantially perpendicular to the top surface of the substrate 100.

A first peripheral active pattern ACT1, which may be defined by a peripheral device isolation layer, may be provided on the first peripheral region PA1 of the substrate 100.

A pair of first dopant regions 144a may be provided in the first peripheral active pattern ACT1. The pair of first dopant regions 144a may be spaced apart from each other in the first direction D1 in the first peripheral active pattern ACT1 with the first gate structure GS1 interposed therebetween. For example, the pair of first dopant regions 144a are positioned at opposing sides of the first gate structure GS1. Here, another region of the first peripheral active pattern ACT1, except a channel region and the pair of first dopant regions 144a, may be a first body region.

The pair of first dopant regions 144a may correspond to source/drain regions. The pair of first dopant regions 144a may be dopant regions having a first conductivity type (e.g., an n-type). The first body region may have a second conductivity type (e.g., a p-type) different from the first conductivity type.

The first gate structure GS1 may be provided on the first peripheral active pattern ACT1. In the present specification, the first gate structure GS1 may also be referred to as a first peripheral gate pattern GS1. The pair of first dopant regions 144a and the first gate structure GS1 may constitute an NMOS transistor.

The first gate structure GS1 may include a first insulating pattern 120a, a second insulating pattern 120b, a first high-k dielectric pattern 122a, a first conductive pattern M1 and a first capping pattern 140a, which are sequentially stacked on the first peripheral active pattern ACT1.

The first insulating pattern 120a and the second insulating pattern 120b in the first gate structure GS1 may be disposed between the first peripheral active pattern ACT1 and the first conductive pattern M1. The first insulating pattern 120a may be disposed to be closer to the first peripheral active pattern ACT1 than the second insulating pattern 120b. For example, the first insulating pattern 120a is disposed between the first peripheral active pattern ACT1 and the second insulating pattern 120b.

The first insulating pattern 120a and the second insulating pattern 120b may have a first thickness TH1 and a second thickness TH2, respectively. A sum of the first thickness TH1 and the second thickness TH2 may range from 12 Å to 13 Å. For example, the first insulating pattern 120a and the second insulating pattern 120b may include silicon oxide.

The first high-k dielectric pattern 122a may be disposed on the second insulating pattern 120b. The first high-k dielectric pattern 122a may include a high-k dielectric material. For example, the first high-k dielectric pattern 122a may include at least one of metal oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO).

The first conductive pattern M1 may be disposed on the first high-k dielectric pattern 122a. The first conductive pattern M1 may include a first lower conductive pattern 130a and a first upper conductive pattern 138a.

The first lower conductive pattern 130a may be disposed on the first high-k dielectric pattern 122a. For example, the first lower conductive pattern 130a may include dopant-doped poly-silicon. The first lower conductive pattern 130a may have the first conductivity type (e.g., the n-type).

The first upper conductive pattern 138a may be disposed on the first lower conductive pattern 130a. For example, the first upper conductive pattern 138a may include a metal such as aluminum (Al), tungsten (W), or copper (Cu).

The first capping pattern 140a may be disposed on the first upper conductive pattern 138a. A level of a top surface of the first capping pattern 140a may correspond to a level of a top surface GS1t of the first gate structure GS1. For example, the first capping pattern 140a may include silicon nitride.

A second peripheral active pattern ACT2 defined by the peripheral device isolation layer may be provided on the second peripheral region PA2 of the substrate 100. The second peripheral active pattern ACT2 may include a first semiconductor material. For example, the first semiconductor material may be silicon (Si). A pair of second dopant regions 144b may be provided in the second peripheral active pattern ACT2. The pair of second dopant regions 144b may be spaced apart from each other in the first direction D1 in the second peripheral active pattern ACT2 with the second gate structure GS2 interposed therebetween. For example, the pair of second dopant regions 144b may be disposed at opposing sides of the second gate structure GS2. Here, another region of the second peripheral active pattern ACT2 except a channel region and the pair of second dopant regions 144b may be defined as a second body region.

The pair of second dopant regions 144b may correspond to source/drain regions. The pair of second dopant regions 144b may be dopant regions having a conductivity type different from the first conductivity type. For example, the pair of second dopant regions 144b may be dopant regions having the second conductivity type (e.g., the p-type). The second body region may have the first conductivity type (e.g., the n-type) different from the second conductivity type.

A channel semiconductor pattern CSL may be provided on the second peripheral active pattern ACT2. The channel semiconductor pattern CSL may include a second semiconductor material. The second semiconductor material may be different from the first semiconductor material, and for example, the second semiconductor material may be silicon-germanium (SiGe). A level of a top surface CSLt of the channel semiconductor pattern CSL may be higher than a level of a top surface 120bt of the second insulating pattern 120b that is described above. For example, the channel semiconductor pattern CSL may include silicon-germanium (SiGe). For example, a thickness CSLD of the channel semiconductor pattern CSL may range from 7 nm to 9 nm.

The second gate structure GS2 may be provided on the second peripheral active pattern ACT2. The channel semiconductor pattern CSL may be disposed between the second peripheral active pattern ACT2 and the second gate structure GS2. In the present specification, the second gate structure GS2 may also be referred to as a second peripheral gate pattern GS2. A level of a top surface GS2t of the second gate structure GS2 may be higher than the level of the top surface GS1t of the first gate structure GS1. A difference between the level of the top surface GS2t of the second gate structure GS2 and the level of the top surface GS1t of the first gate structure GS1 may be 8 nm or less. The pair of second dopant regions 144b and the second gate structure GS2 may constitute a PMOS transistor.

The second gate structure GS2 may include a third insulating pattern 120c, a second high-k dielectric pattern 122b, a second conductive pattern M2 and a second capping pattern 140b, which are sequentially stacked on the channel semiconductor pattern CSL.

The third insulating pattern 120c in the second gate structure GS2 may be disposed between the channel semiconductor pattern CSL and the second conductive pattern M2. In other words, the channel semiconductor pattern CSL may be disposed between the second peripheral active pattern ACT2 and the third insulating pattern 120c, and the third insulating pattern 120c may be in contact with the channel semiconductor pattern CSL. The level of the top surface 120ct of the third insulating pattern 120c may be higher than the level of the top surface 120bt of the second insulating pattern 120b.

The third insulating pattern 120c may have a third thickness TH3. The third thickness TH3 may be 15% or less of a thickness of the second gate structure GS2. The third thickness TH3 may range from 10 Å to 13 Å. For example, the third thickness TH3 may range from 12 Å to 13 Å. In embodiments of the present inventive concept, the sum of the first thickness TH1 of the first insulating pattern 120a and the second thickness TH2 of the second insulating pattern 120b may range from 90% to 110% of the third thickness TH3 of the third insulating pattern 120c. In embodiments of the present inventive concept, the third thickness TH3 of the third insulating pattern 120c may be substantially equal to the sum of the first thickness TH1 of the first insulating pattern 120a and the second thickness TH2 of the second insulating pattern 120b. The third insulating pattern 120c may include, for example, silicon oxide.

A bond energy between the first insulating pattern 120a and the first peripheral active pattern ACT1 may be greater than a bond energy between the third insulating pattern 120c and the channel semiconductor pattern CSL.

The second high-k dielectric pattern 122b may be disposed on the third insulating pattern 120c. The third thickness TH3 of the third insulating pattern 120c may be 30% or less of a thickness 122bd of the second high-k dielectric pattern 122b. The second high-k dielectric pattern 122b may include a high-k dielectric material. For example, the second high-k dielectric pattern 122b may include at least one of metal oxide, hafnium oxide (HfO), hafnium silicate (HfSiO), hafnium oxynitride (HfON), hafnium silicon oxynitride (HfSiON), lanthanum oxide (LaO), lanthanum aluminum oxide (LaAlO), zirconium oxide (ZrO), zirconium silicate (ZrSiO), zirconium oxynitride (ZrON), zirconium silicon oxynitride (ZrSiON), tantalum oxide (TaO), titanium oxide (TiO), barium strontium titanium oxide (BaSrTiO), barium titanium oxide (BaTiO), strontium titanium oxide (SrTiO), yttrium oxide (YO), aluminum oxide (AlO), or lead scandium tantalum oxide (PbScTaO).

The second conductive pattern M2 may be disposed on the second high-k dielectric pattern 122b. The second conductive pattern M2 may include a second lower conductive pattern 130b and a second upper conductive pattern 138b.

The second lower conductive pattern 130b may be disposed on the second high-k dielectric pattern 122b. For example, the second lower conductive pattern 130b may include dopant-doped poly-silicon. The second lower conductive pattern 130b may have the second conductivity type (e.g., the p-type).

The second upper conductive pattern 138b may be disposed on the second lower conductive pattern 130b. For example, the second upper conductive pattern 138b may include a metal such as aluminum (Al), tungsten (W), or copper (Cu).

The second capping pattern 140b may be disposed on the second upper conductive pattern 138b. A level of a top surface of the second capping pattern 140b may be substantially the same or the same as the level of the top surface GS2t of the second gate structure GS2. The second capping pattern 140b may include, for example, silicon nitride.

First spacers 142 may be disposed on side surfaces of each of the first gate structure GS1 and the second gate structure GS2, respectively. The first spacers 142 may be spaced apart from each other in the first direction D1 with each of the first and second gate structures GS1 and GS2 interposed therebetween. For example, each of the first spacers 142 may include at least one of silicon nitride, silicon oxide, or silicon oxynitride.

A first interlayer insulating layer 146 may be disposed on the first and second peripheral active patterns ACT1 and ACT2 and may cover the first gate structure GS1, the second gate structure GS2 and the first spacers 142. For example, the first interlayer insulating layer 146 may include at least one of silicon nitride or silicon oxide.

A capping layer 148 may cover a top surface of the first interlayer insulating layer 146. The capping layer 148 may include at least one of, for example, silicon nitride, silicon oxide, or silicon oxynitride. A plurality of interconnection layers may be provided on the capping layer 148.

In the semiconductor device according to embodiments of the present inventive concept, the sum of the first and second thicknesses TH1 and TH2 of the first and second insulating patterns 120a and 120b that are included in the first gate structure GS1 may range from 90% to 110% of the third thickness TH3 of the third insulating pattern 120c that is included in the second gate structure GS2. In embodiments of the present inventive concept, the third thickness TH3 may be 30% or less of the thickness 122bd of the second high-k dielectric pattern 122b. In embodiments of the present inventive concept, the third thickness TH3 may range from 12 Å to 13 Å.

As a result, a height difference between the first gate structure GS1, which is on the first peripheral active pattern ACT1, and the second gate structure GS2, which is on the second peripheral active pattern ACT2, may be reduced. In addition, since the thickness of the third insulating pattern 120c is reduced, a value of a current flowing through the second peripheral active pattern ACT2 may be increased.

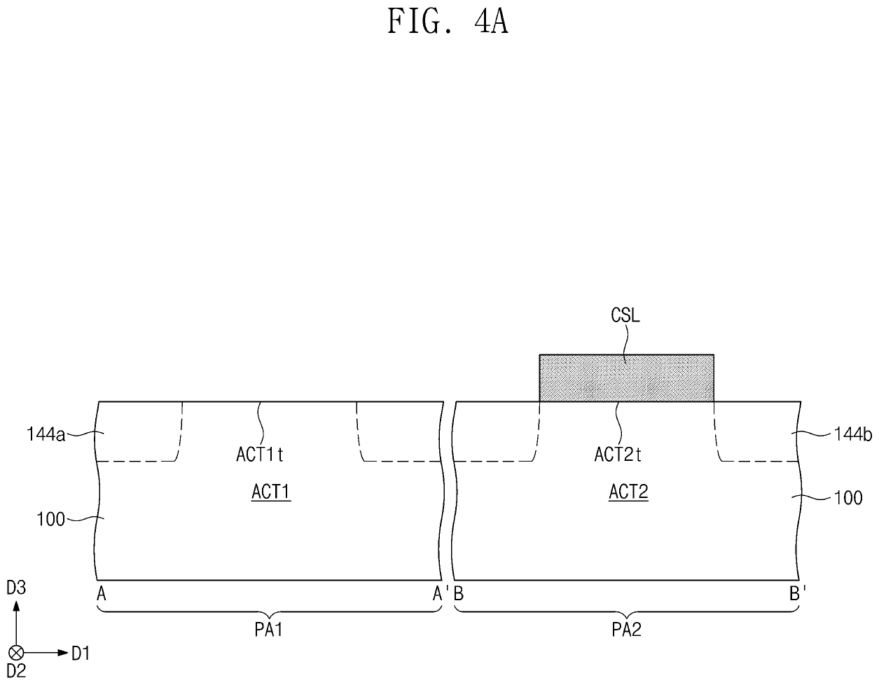

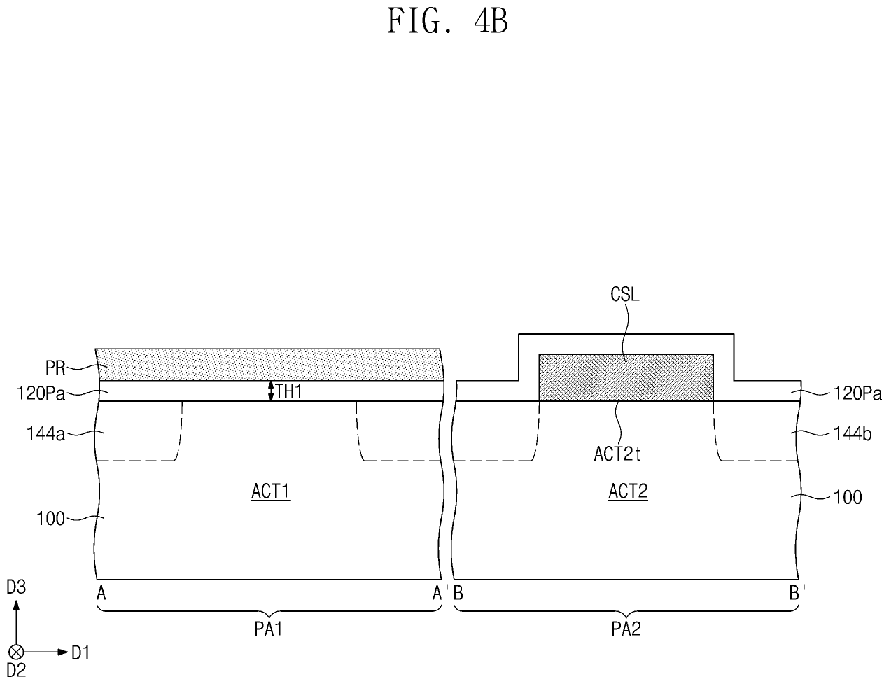

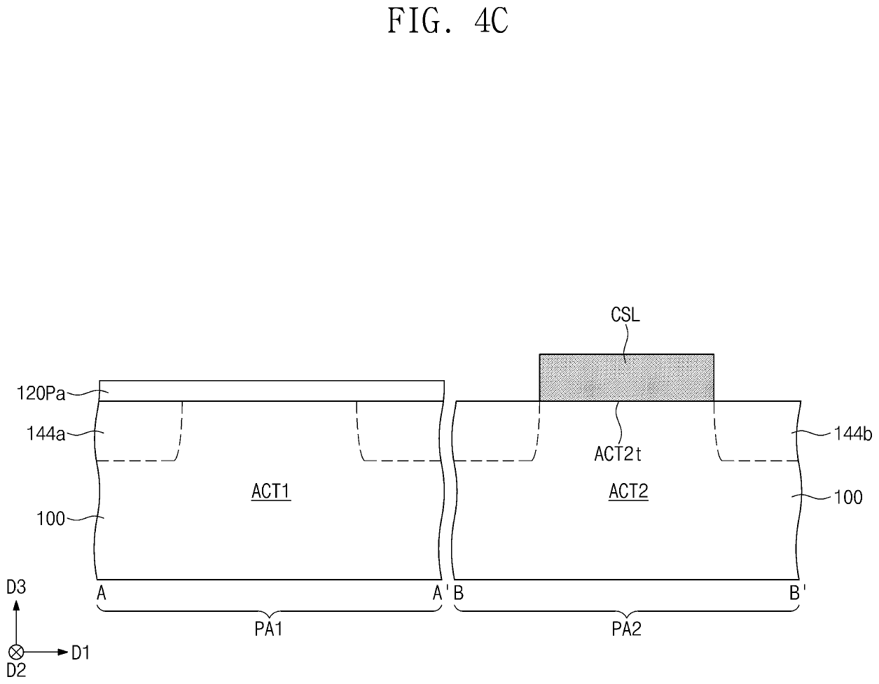

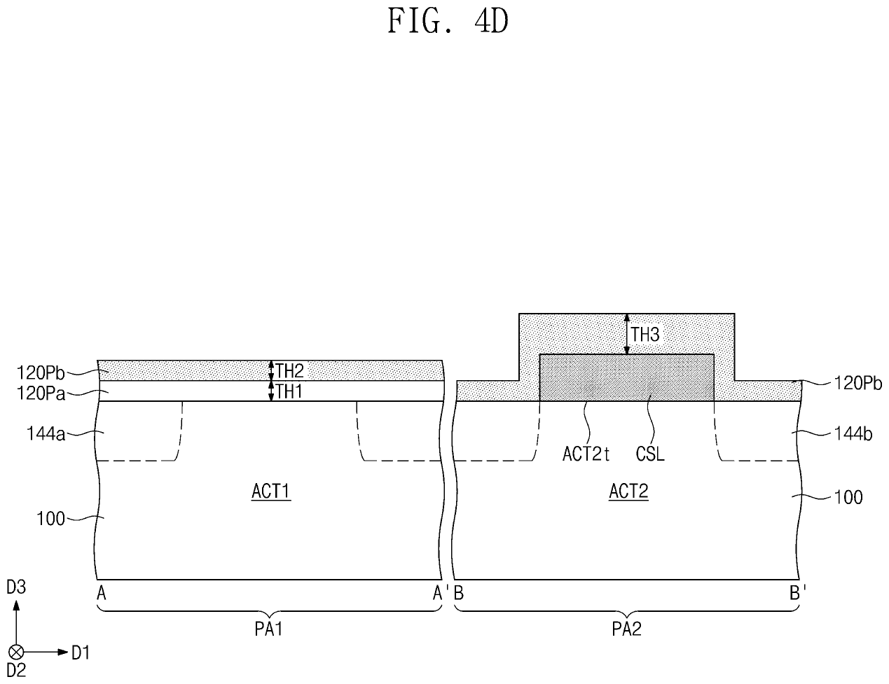

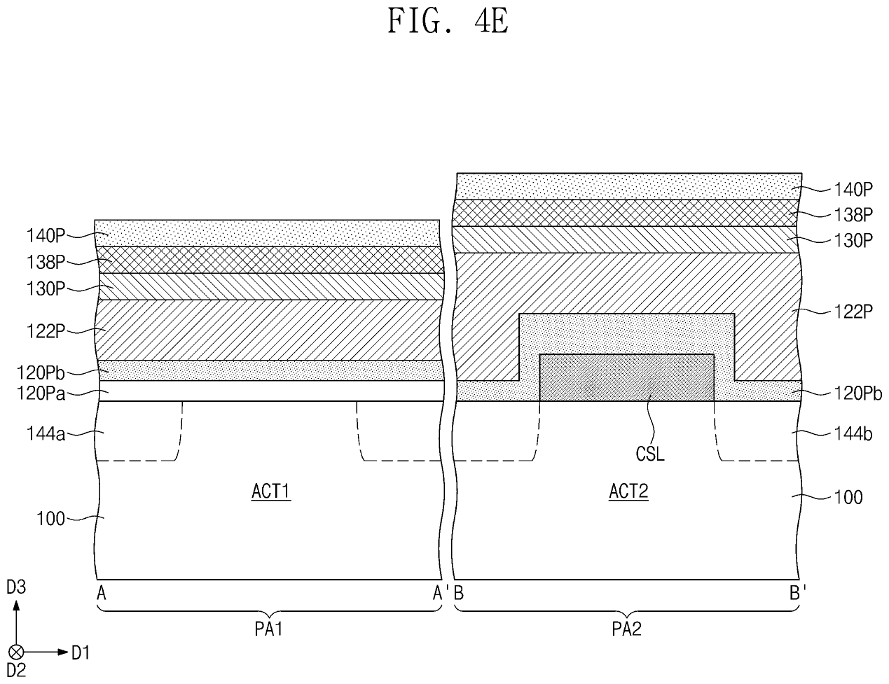

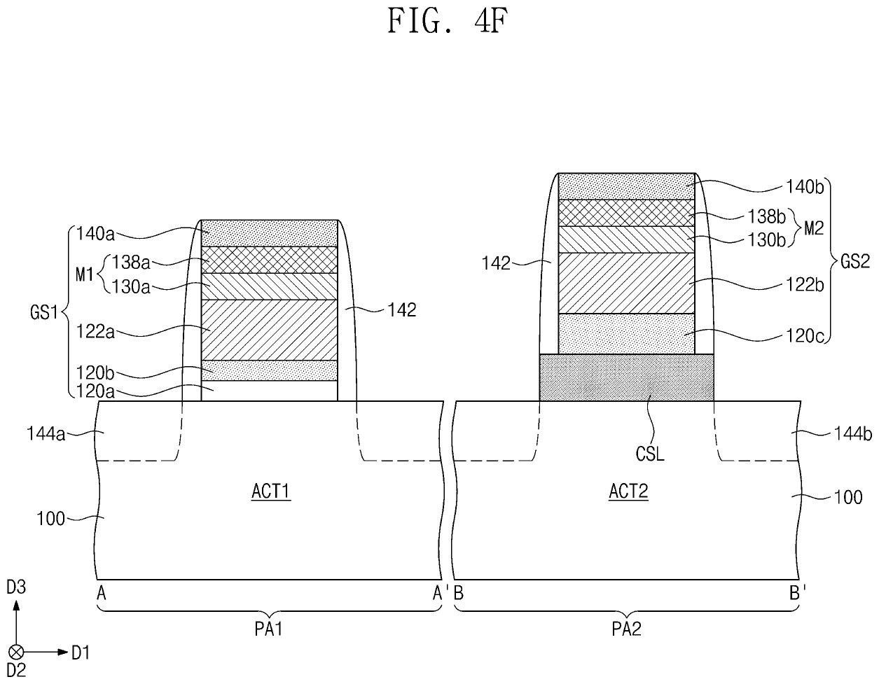

FIGS. 4A to 4F are cross-sectional views illustrating a method of manufacturing a semiconductor device according to embodiments of the present inventive concept. More particularly, FIGS. 4A to 4F are cross-sectional views illustrating a method of manufacturing the semiconductor device shown in FIG. 3.

Referring to FIG. 4A, a first peripheral active pattern ACT1 defined by a peripheral device isolation layer and including first dopant regions 144a may be provided, and a second peripheral active pattern ACT2 defined by the peripheral device isolation layer and including second dopant regions 144b may be provided. In addition, a channel semiconductor pattern CSL that is on the second peripheral active pattern ACT2 may be provided.

For example, a channel semiconductor layer may be formed on the second peripheral active pattern ACT2 by a selective epitaxial growth (SEG) process. Thereafter, an etching process may be performed on the channel semiconductor layer to form the channel semiconductor pattern CSL. The channel semiconductor pattern CSL may have a shape in which a width of the channel semiconductor layer in the first direction D1 is reduced. After the formation of the channel semiconductor pattern CSL, a dopant implantation process may be performed on the second peripheral active pattern ACT2, except a portion of the second peripheral active pattern ACT2 that is covered by the channel semiconductor pattern CSL, thereby forming the second dopant regions 144b.

Referring to FIG. 4B, a first insulating layer 120Pa may be formed on the first peripheral active pattern ACT1, the second peripheral active pattern ACT2, and the channel semiconductor pattern CSL. At this time, the first insulating layer 120Pa formed on the second peripheral active pattern ACT2 may cover a side surface and a top surface of the channel semiconductor pattern CSL. A thickness of the first insulating layer 120Pa formed on the first peripheral active pattern ACT1 may be equal to the first thickness TH1 that is described above.

The formation of the first insulating layer 120Pa may be performed by an ISSG (in-situ steam generation) process. For example, the first insulating layer 120Pa may be formed by using oxygen radicals (O radicals) that are generated by a reaction of hydrogen molecules (H₂) and oxygen molecules (O₂) as shown in the following reaction. At this time, the oxygen molecules (O₂) may be in a vapor state.

3H₂+3O₂→2H₂O+2O*+2OH

In embodiments of the present inventive concept, the ISSG (in-situ steam generation) process may be performed by using ozone (O₃), not the oxygen molecules (O₂).

In embodiments of the present inventive concept, the first insulating layer 120Pa may be formed by using oxygen radicals (O radicals) generated by performing a thermal treatment process on oxygen molecules (O₂), instead of the ISSG (in-situ steam generation) process.

Thereafter, a mask pattern PR may be formed to protect the first insulating layer 120Pa that is formed on the first peripheral active pattern ACT1. At this time, the mask pattern PR may be formed to expose a portion of the first insulating layer 120Pa that is formed on a top surface of the second peripheral active pattern ACT2 and a portion of the first insulating layer 120Pa that is formed on the top surface and the side surface of the channel semiconductor pattern CSL.

Referring to FIG. 4C, an etching process may be performed on the first peripheral active pattern ACT1 and the second peripheral active pattern ACT2 by using the mask pattern PR that is formed on the first peripheral active pattern ACT1 as an etch mask. The etching process may include a wet etching process or a dry etching process. The first insulating layer 120Pa that is formed on the second peripheral active pattern ACT2 may be removed by the etching process. Next, the mask pattern PR may be removed, and the first insulating layer 120Pa may remain on the first peripheral active pattern ACT1. After the removal of the mask pattern PR, a cleaning process may be performed to remove a by-product and a contaminant that are on the first insulating layer 120Pa and the second peripheral active pattern ACT2.

Referring to FIG. 4D, a second insulating layer 120Pb may be formed on the second peripheral active pattern ACT2 and the first insulating layer 120Pa that is formed on the first peripheral active pattern ACT1. At this time, the second insulating layer 120Pb that is on the second peripheral active pattern ACT2 may cover the side surface and the top surface of the channel semiconductor pattern CSL.

The second insulating layer 120Pb may be formed by using oxygen radicals (O radicals) that are generated by irradiating ultraviolet light to oxygen molecules (O₂) as shown in the following reaction.

UV lamp+O₂→O*+O*

In embodiments of the present inventive concept, the second insulating layer 120Pb may be formed by using oxygen radicals (O radicals) that are generated by performing a thermal treatment process on oxygen molecules (O₂), instead of the irradiating of the ultraviolet light.

In embodiments of the present inventive concept, the second insulating layer 120Pb may be formed by using oxygen radicals (O radicals) that are generated by irradiating ultraviolet light to ozone (O₃) as shown in the following reaction.

UV lamp+O₃→O₂+O*

At this time, the second insulating layer 120Pb that is formed on the first peripheral active pattern ACT1 may have a second thickness TH2, and the second insulating layer 120Pb that is formed on the top surface of the channel semiconductor pattern CSL may be formed to have a third thickness TH3. Due to high oxidizing power of germanium (Ge) that is included in the channel semiconductor pattern CSL, the third thickness TH3 of the second insulating layer 120Pb that is formed on the top surface of the channel semiconductor pattern CSL may be larger than the second thickness TH2 of the second insulating layer 120Pb that is formed on the first peripheral active pattern ACT1. A sum of the first thickness TH1 and the second thickness TH2 may range from 90% to 110% of the third thickness TH3.

Referring to FIG. 4E, a high-k dielectric layer 122P, a lower conductive layer 130P, an upper conductive layer 138P and a capping layer 140P may be sequentially formed on the second insulating layer 120Pb. At this time, the high-k dielectric layer 122P that is disposed on the second peripheral active pattern ACT2 may be formed to cover the second insulating layer 120Pb.

Referring to FIG. 4F, a patterning process may be performed on the first insulating layer 120Pa, the second insulating layer 120Pb, the high-k dielectric layer 122P, the lower conductive layer 130P, the upper conductive layer 138P and the capping layer 140P that are formed on the first peripheral active pattern ACT1, thereby forming a first gate structure GS1 that includes a first insulating pattern 120a, a second insulating pattern 120b, a first high-k dielectric pattern 122a, a first lower conductive pattern 130a, a first upper conductive pattern 138a and a first capping pattern 140a.

In addition, the patterning process may be performed on the second insulating layer 120Pb, the high-k dielectric layer 122P, the lower conductive layer 130P, the upper conductive layer 138P and the capping layer 140P that are formed on the second peripheral active pattern ACT2, thereby forming a second gate structure GS2 that includes a third insulating pattern 120c, a second high-k dielectric pattern 122b, a second lower conductive pattern 130b, a second upper conductive pattern 138b and a second capping pattern 140b. For example, the patterning process may include an etching process using a mask pattern.

Next, first spacers 142 may be formed on side surfaces of each of the first gate structure GS1 and the second gate structure GS2. The first spacers 142 may be spaced apart from each other in the first direction D1 with each of the first and second gate structures GS1 and GS2 interposed therebetween. For example, the first gate structure GS1 may be disposed between a pair of first spacers 142, and the second gate structure GS2 may be disposed between a pair of first spacers 142.

Thereafter, referring again to FIG. 3, a first interlayer insulating layer 146 may be formed to cover the first and second gate structures GS1 and GS2, and then, a capping layer 148 may be formed to cover the first interlayer insulating layer 146, thereby manufacturing the semiconductor device according to embodiments of the present inventive concept.

In the method of manufacturing a semiconductor device according to embodiments of the present inventive concept, the first insulating pattern 120a may be formed on the first peripheral active pattern ACT1 by using the ISSG (in-situ steam generation) process, and then, the second and third insulating patterns 120b and 120c may be formed on the first and second peripheral active patterns ACT1 and ACT2, respectively, by using the oxygen radicals (O radicals) that are generated by irradiating the ultraviolet light to the oxygen molecules (02). Here, since the first insulating pattern 120a is formed by the ISSG (in-situ steam generation) process, the thickness of the first insulating pattern 120a may be accurately controlled, and defects of the first peripheral active pattern ACT1 may be reduced. As a result, a value of a current flowing through the first peripheral active pattern ACT1 may be increased.

In addition, in the method of manufacturing a semiconductor device according to embodiments of the present inventive concept, the first insulating pattern 120a, which is formed on the first peripheral active pattern ACT1, and the third insulating pattern 120c, which is formed on the second peripheral active pattern ACT2, may be formed by using the ISSG (in-situ steam generation) process and the ultraviolet (UV) light, respectively, and may be formed independently of each other. Thus, the third thickness TH3 of the third insulating pattern 120c may be adjusted regardless of the formation process of the first insulating pattern 120a that is formed by the ISSG (in-situ steam generation) process. In other words, the third thickness TH3 of the third insulating pattern 120c may be adjusted to 110% or less of the sum of the first thickness TH1 of the first insulating pattern 120a and the second thickness TH2 of the second insulating pattern 120b, and thus, a height difference between the transistors that are formed by the first and second gate structures GS1 and GS2 may be reduced.

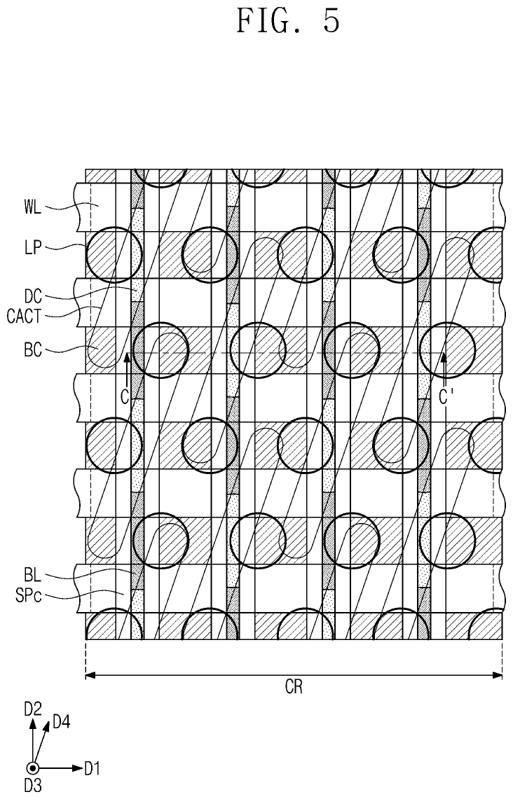

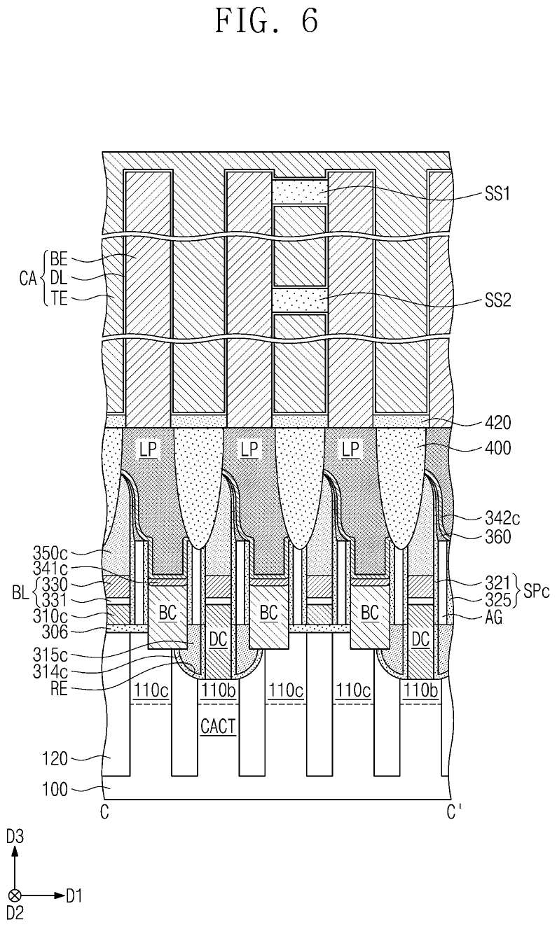

FIG. 5 is a plan view illustrating a semiconductor device according to embodiments of the present inventive concept. FIG. 6 is a cross-sectional view taken along a line C-C′ of FIG. 5 to illustrate a semiconductor device according to embodiments of the present inventive concept.

Referring to FIGS. 5 and 6, a substrate 100 including a cell region CR may be provided. The cell region CR may be a region of the substrate 100, on which the cell blocks CB of FIG. 1 are provided.

Cell active patterns CACT may be disposed on the cell region CR of the substrate 100. The cell active patterns CACT may be spaced apart from each other in the first direction D1 and the second direction D2 when viewed in a plan view. Each of the cell active patterns CACT may have a bar shape that extends in a fourth direction D4, which is parallel to a bottom surface of the substrate 100 and intersects the first direction D1 and the second direction D2.

A device isolation layer 120 may be disposed between the cell active patterns CACT on the cell region CR. The device isolation layer 120 may be disposed in the substrate 100 to define the cell active patterns CACT. The cell active patterns CACT may be portions of the substrate 100.

Word lines WL may intersect the cell active patterns CACT and the device isolation layer 120 on the cell region CR. The word lines WL may be disposed in grooves that are formed in the cell active patterns CACT and the device isolation layer 120. The word lines WL may extend in the first direction D1 and may be spaced apart from each other in the second direction D2. The word lines WL may be buried in the substrate 100.

First cell dopant regions 110b and second cell dopant regions 110c may be provided in the cell active patterns CACT. Each of the first cell dopant regions 110b may be provided between a pair of the word lines WL intersecting each of the cell active patterns CACT. The second cell dopant regions 110c may be provided in both edge regions of each of the cell active patterns CACT.

A buffer pattern 306 may cover the cell active patterns CACT, the device isolation layer 120 and the word lines WL on the substrate 100. For example, the buffer pattern 306 may include silicon oxide, silicon nitride, and/or silicon oxynitride.

Bit lines BL may be disposed on the buffer pattern 306. The bit lines BL may extend in the second direction D2 and may be spaced apart from each other in the first direction D1. Each of the bit lines BL may include a barrier pattern 331 and a metal-containing pattern 330, which are sequentially stacked on the buffer pattern 306.

Cell poly-silicon patterns 310c may be disposed between the bit lines BL and the buffer pattern 306. A first cell ohmic pattern may be provided between the barrier pattern 331 and a corresponding cell poly-silicon pattern 310c. For example, the first cell ohmic pattern may include a silicide.

Bit line contacts DC may be disposed between the bit lines BL and the first cell dopant regions 110b, respectively. The bit lines BL may be electrically connected to the first cell dopant regions 110b through the bit line contacts DC. The bit line contacts DC may include, for example, dopant-doped poly-silicon or undoped poly-silicon.

The bit line contacts DC may be disposed in a recess portion RE. The recess portion RE may be provided in upper portions of the first cell dopant regions 110b and an upper portion of the device isolation layer 120 that is adjacent to the bit line contacts DC. A first filling insulation pattern 314c and a second filling insulation pattern 315c may fill a remaining portion of the recess portion RE.

A cell capping pattern 350c may extend in the second direction D2 on each of the bit lines BL. For example, the cell capping pattern 350c may include silicon nitride.

A bit line spacer SPc may cover a side surface of each of the cell poly-silicon patterns 310c, an upper side surface of each of the bit line contacts DC, a side surface of each of the bit lines BL, and a side surface of the cell capping pattern 350c. The bit line spacer SPc may extend in the second direction D2 on a side surface of each of the bit lines BL.

The bit line spacer SPc may include a first sub-spacer 321 and a second sub-spacer 325, which are spaced apart from each other. For example, the first sub-spacer 321 and the second sub-spacer 325 may be spaced apart from each other by an air gap AG. The first sub-spacer 321 may be in contact with the side surface of each of the bit lines BL and may extend onto the side surface of the cell capping pattern 350c. The second sub-spacer 325 may be provided along a side surface of the first sub-spacer 321. For example, each of the first and second sub-spacers 321 and 325 may include silicon nitride.

An upper spacer 360 may cover a portion of the side surface of the first sub-spacer 321 and may extend onto a top surface of the second sub-spacer 325. The upper spacer 360 may further cover the air gap AG.

Storage node contacts BC may be disposed between the bit lines BL that are adjacent to each other. The storage node contacts BC may be spaced apart from each other in the first direction D1 and the second direction D2. The storage node contacts BC may include dopant-doped poly-silicon or undoped poly-silicon.

A second cell ohmic pattern 341c may be disposed on each of the storage node contacts BC. For example, the second cell ohmic pattern 341c may include a silicide.

A cell diffusion barrier pattern 342c may conformally cover the second cell ohmic pattern 341c, the bit line spacer SPc, and the cell capping pattern 350c. For example, the cell diffusion barrier pattern 342c may include a metal nitride (e.g., TiN, TSN, TaN, etc.). The second cell ohmic pattern 341c may be disposed between the cell diffusion barrier pattern 342c and each of the storage node contacts BC.

Landing pads LP may be disposed on the storage node contacts BC, respectively. The landing pads LP may be spaced apart from each other in the first direction D1 and the second direction D2. The landing pads LP may include a metal (e.g., tungsten).

A filling pattern 400 may at least partially surround each of the landing pads LP when viewed in a plan view. The filling pattern 400 may be disposed between the landing pads LP that are adjacent to each other.

Lower electrodes BE may be disposed on the landing pads LP, respectively. For example, the lower electrodes BE may include at least one of dopant-doped poly-silicon, a metal nitride (e.g., titanium nitride), or a metal (e.g., tungsten, aluminum or copper). For example, each of the lower electrodes BE may have a circular pillar shape, a hollow cylinder or cup shape; however, the present inventive concept is not limited thereto. An upper support pattern SS1 may support upper side surfaces of the lower electrodes BE, and a lower support pattern SS2 may support lower side surfaces of the lower electrodes BE. The upper and lower support patterns SS1 and SS2 may include an insulating material such as silicon nitride, silicon oxide, and/or silicon oxynitride.

An etch stop pattern 420 may be provided on the filling pattern 400 between the lower electrodes BE. A dielectric layer DL may cover surfaces of the lower electrodes BE and surfaces of the upper and lower support patterns SS1 and SS2. For example, the dielectric layer DL may include at least one of silicon oxide, silicon nitride, silicon oxynitride, or a high-k dielectric material. An upper electrode TE may be disposed on the dielectric layer DL and may fill a space between the lower electrodes BE. For example, the upper electrode TE may include at least one of dopant-doped poly-silicon, dopant-doped silicon-germanium, a metal nitride (e.g., titanium nitride), or a metal (e.g., tungsten, aluminum or copper). The lower electrodes BE, the dielectric layer DL and the upper electrode TE may constitute capacitors CA.

The semiconductor device according to embodiments of the present inventive concept may include a first gate structure, which is on a first active pattern, and a second gate structure, which is on a second active pattern. The first gate structure may include a first insulating pattern, a second insulating pattern and a first high-k dielectric pattern, which are sequentially stacked on the first active pattern. The second gate structure may include a third insulating pattern and a second high-k dielectric pattern, which are sequentially stacked on the second active pattern. Here, the thickness of the third insulating pattern may range from 12 Å to 13 Å. As a result, a height difference between the first gate structure and the second gate structure may be reduced, and a value of a current flowing through the second active pattern may be increased by the thin thickness of the third insulating pattern.

In addition, the first insulating pattern may be formed on the first active pattern by the ISSG (in-situ steam generation) process, and the third insulating pattern may be separately formed by using the ultraviolet (UV) light after the formation of the first insulating pattern. As a result, interface characteristics of the first active pattern may be improved to increase a value of a current flowing through the first active pattern, and the thickness of the third insulating pattern may be adjusted to 110% or less of the sum of the thickness of the first insulating pattern and the thickness of the second insulating pattern regardless of the process of forming the first insulating pattern.

While the present inventive concept has been described with reference to example embodiments thereof, it will be understood by those of ordinary skill in the art that various changes in form and details may be made thereto without departing from the spirit and scope of the present inventive concept.

What is claimed is:

1. A semiconductor device comprising:
a substrate including a first active pattern and a second active pattern which are spaced apart from each other;
a first gate structure disposed on the first active pattern;
a second gate structure disposed on the second active pattern; and
a channel semiconductor pattern disposed between the second active pattern and the second gate structure,
wherein the first gate structure comprises: a first insulating pattern, a second insulating pattern and a first high-k dielectric pattern, which are stacked on the first active pattern,
wherein the second gate structure comprises: a third insulating pattern and a second high-k dielectric pattern, which are stacked on the channel semiconductor pattern, and
wherein a thickness of the third insulating pattern ranges from 12 Å to 13 Å.

2. The semiconductor device of claim 1, wherein the second active pattern includes a first semiconductor material,
wherein the channel semiconductor pattern includes a second semiconductor material, and
wherein the first semiconductor material is different from the second semiconductor material.

3. The semiconductor device of claim 2, wherein a level of a top surface of the channel semiconductor pattern is higher than a level of a top surface of the second insulating pattern.

4. The semiconductor device of claim 1, wherein the first gate structure further comprises: a first lower conductive pattern, a first upper conductive pattern and a first capping pattern, which are stacked on the first high-k dielectric pattern, and
wherein the second gate structure further comprises: a second lower conductive pattern, a second upper conductive pattern and a second capping pattern, which are stacked on the second high-k dielectric pattern.

5. The semiconductor device of claim 1, wherein the first to third insulating patterns include silicon oxide.

6. The semiconductor device of claim 1, wherein a difference between a level of a top surface of the first gate structure and a level of a top surface of the second gate structure is 8 nm or less.

7. The semiconductor device of claim 1, wherein the channel semiconductor pattern includes silicon-germanium (SiGe),
wherein the first active pattern includes: first dopant regions spaced apart from each other in a first direction with the first gate structure interposed between the first dopant regions, wherein the first direction is parallel to a top surface of the substrate,
wherein the second active pattern includes: second dopant regions spaced apart from each other in the first direction with the second gate structure interposed between the second dopant regions,
wherein the first dopant regions have a first conductivity type,
wherein the second dopant regions have a second conductivity type, and
wherein the first conductivity type is different from the second conductivity type.

8. The semiconductor device of claim 1, wherein a bond energy between the first active pattern and the first insulating pattern is greater than a bond energy between the channel semiconductor pattern and the third insulating pattern.

9. The semiconductor device of claim 1, wherein a sum of a thickness of the first insulating pattern and a thickness of the second insulating pattern is substantially equal to the thickness of the third insulating pattern.

10. A semiconductor device comprising:
a substrate including a first active pattern and a second active pattern which are spaced apart from each other;
a first gate structure disposed on the first active pattern; and
a second gate structure disposed on the second active pattern,
wherein the first gate structure comprises: a first insulating pattern, a second insulating pattern, a first high-k dielectric pattern and a first conductive pattern, which are stacked on the first active pattern,
wherein the second gate structure comprises: a third insulating pattern, a second high-k dielectric pattern and a second conductive pattern, which are stacked on the second active pattern,
wherein the first insulating pattern is disposed between the first active pattern and the second insulating pattern, and
wherein a thickness of the third insulating pattern is 30% or less of a thickness of the second high-k dielectric pattern.

11. The semiconductor device of claim 10, wherein a difference between a level of a top surface of the first gate structure and a level of a top surface of the second gate structure is 8 nm or less.

12. The semiconductor device of claim 10, further comprising:
a channel semiconductor pattern disposed between the second active pattern and the third insulating pattern,
wherein a level of a top surface of the third insulating pattern is higher than a level of a top surface of the second insulating pattern.

13. The semiconductor device of claim 10, wherein each of the first to third insulating patterns includes silicon oxide.

14. The semiconductor device of claim 10, further comprising:
an interlayer insulating layer disposed on the first and second active patterns, and covering the first gate structure and the second gate structure.

15. A semiconductor device comprising:
a substrate including cell active patterns on a cell region, and a first peripheral active pattern and a second peripheral active pattern spaced apart from each other on a peripheral region that is adjacent to the cell region;
word lines disposed in the substrate and intersecting the cell active patterns;
bit lines disposed on the substrate and intersecting the word lines;
a bit line contact disposed on a central portion of each of the cell active patterns and connected to a corresponding one of the bit lines;
storage node contacts disposed on end portions of each of the cell active patterns;
a landing pad disposed on each of the storage node contacts;
a capacitor disposed on the landing pad;
a first peripheral gate pattern disposed on the first peripheral active pattern;
a second peripheral gate pattern disposed on the second peripheral active pattern; and
a channel semiconductor pattern disposed between the second peripheral active pattern and the second peripheral gate pattern,
wherein the first peripheral gate pattern comprises: a first insulating pattern, a second insulating pattern, a first high-k dielectric pattern, a first lower conductive pattern, a first upper conductive pattern and a first capping pattern, which are stacked on the first peripheral active pattern,
wherein the second peripheral gate pattern comprises: a third insulating pattern, a second high-k dielectric pattern, a second lower conductive pattern, a second upper conductive pattern and a second capping pattern, which are stacked on the channel semiconductor pattern, and
wherein a sum of a thickness of the first insulating pattern and a thickness of the second insulating pattern ranges from 90% to 110% of a thickness of the third insulating pattern.

16. The semiconductor device of claim 15, wherein each of the first to third insulating patterns include silicon oxide, and
wherein the channel semiconductor pattern includes silicon-germanium (SiGe).

17. The semiconductor device of claim 15, further comprising:
spacers on side surfaces of each of the first peripheral gate pattern and second peripheral gate pattern;
an interlayer insulating layer disposed on the first peripheral gate pattern and second peripheral active pattern; and
a peripheral capping layer disposed on the interlayer insulating layer.

18. The semiconductor device of claim 15, wherein a level of a top surface of the channel semiconductor pattern is higher than a level of a top surface of the second insulating pattern.

19. The semiconductor device of claim 15, wherein the sum of the thickness of the first insulating pattern and the thickness of the second insulating pattern ranges from 12 Å to 13 Å.

20. The semiconductor device of claim 15, wherein a difference between a level of a top surface of the first peripheral gate pattern and a level of a top surface of the second peripheral gate pattern is 8 nm or less.
